(19) United States
(12) Patent Application Publication
(10) Pub. No.: US 2013/0168553 A1
(43) Pub. Date: Jul. 4, 2013

(54) Thermally-Sensitive Optocoupler

(71) Applicants: Chee Mang Wong, Singapore (SG); Yik Loong Leong, Singapore (SG); Stephanie Febianty Lie, Singapore (SG)

(72) Inventors: Chee Mang Wong, Singapore (SG); Yik Loong Leong, Singapore (SG); Stephanie Febianty Lie, Singapore (SG)

(73) Assignee: Avago Technologies ECBU IP (Singapore) Pte. Ltd., Fort Collins, CO (US)

(21) Appl. No.: 13/353,303

(22) Filed: Jan. 18, 2012

Related U.S. Application Data
(63) Continuation-in-part of application No. 13/342,227, filed on Jan. 3, 2012.

(51) Int. Cl. H01L 31/167; G01J 5/20

(52) U.S. Cl. 250/341.1; 257/82; 257/E31.108

(57) ABSTRACT

Various embodiments of methods and devices are provided for a thermally-sensitive optocoupler package. A layer in the optocoupler package has an upper surface and a lower surface, and comprises a thermally-sensitive material. In the package, an LED emits infrared or near-infrared light and a photodetector receives at least a portion of such emitted light and in response provides isolated output signals therefrom. The LED is located above the upper surface, and the photodetector is located beneath the lower surface. The thermally-sensitive material is configured such that an amount of light emitted by the LED, incident on the material and the layer, and transmitted through the material and the layer, changes in accordance with changes in ambient temperature or local thermal conditions.

### RELATED APPLICATION

This patent application is a continuation-in-part of, and claims priority and other benefits from the filing date of, U.S. patent application Ser. No. 13/342,227 filed Jan. 3, 2012 entitled “Optocoupler with Multiple Photodetectors and Improved Feedback Control of LED” to Chee Mang Wong et al. (hereafter “the '227 patent application”), the entirety of which is hereby incorporated by reference herein.

### FIELD OF THE INVENTION

Various embodiments of the invention described herein relate to the field of optocouplers and opto-isolators.

### BACKGROUND

In electronics, an optocoupler, also known as an opto-isolator photocoupler, or optical isolator, is an electronic device that transfers electrical signals using light waves to provide coupling with electrical isolation between the input and output of the optocoupler. The main purpose of an optocoupler is to prevent high voltages or rapidly changing voltages on one side of the optocoupler from damaging components or distorting transmissions on the other side of the optocoupler. By way of example, some commercially available optocouplers are designed to withstand input-to-output voltages of up to 10 kV and voltage transients with speeds up to 10 kV/usec.

In an optocoupler, input and output sides of the device are connected with a beam of light (typically falling in the infrared or near-infrared spectrum) modulated by input currents proportional to the electrical signals input to the device. The optocoupler transforms the input electrical signals into light, sends the corresponding light signals across a dielectric channel, captures the transmitted light signals on the output side of the optocoupler, and transforms the transmitted light signals back into output electric signals. Some optocouplers employ infrared or near-infrared light emitting diodes (LEDs) to transmit the light signals and photodetectors to detect the light signals and convert them into output electrical signals.

Some optocouplers include side-by-side closely matched photodetectors, where one the photodetectors is employed to monitor and stabilize the light output of the LED to reduce the effects of non-linearity, drift and aging of the LED, and the other photodetector is employed to generate output signals. See, for example, Avago Technologies™ “HCNR200 and HCNR201 High-Linearity Analog Optocouplers,” Dec. 10, 2011, the Data Sheet for which is filed on even date herewith in an accompanying Information Disclosure Statement, the entirety of which is hereby incorporated by reference herein.

One problem with some commercially-available optocouplers is that the outputs provided thereby can vary according to changes in ambient temperature or local thermal environment, which can introduce yet another undesired variable into output signals.

Many commercially available optocouplers are provided in standard 8-pin dual in-line (DIP) or other standard format packages. While in such packages feedback control and modulation of the LEDs disposed therein on the basis of the changes in ambient temperature, local thermal conditions, or detected light signals is often desirable, doing so may require a package that is larger and has more complicated circuitry than is desired.

Among other things, what is needed is an optocoupler package having improved stability under varying temperature or thermal conditions.

### SUMMARY

In one embodiment, there is provided a thermally-sensitive optocoupler package comprising a layer comprising a thermally-sensitive material, the layer having an upper surface and a lower surface, at least one light emitting diode (LED) configured to emit infrared or near-infrared light in proportion to at least one predetermined characteristic of the input signals, and at least one photodetector configured to provide isolated output signals therefrom, wherein the LED is located above the upper surface of the layer, the photodetector is located beneath the lower surface of the layer, the thermally-sensitive material is configured such that an amount of light emitted by the LED, incident on the material, and transmitted through the material and the layer changes in accordance with changes in ambient temperature or local thermal conditions, and at least portions of the light transmitted through the layer are incident on the photodetector to provide the isolated output signals therefrom.

In another embodiment, there is provided a method of operating a thermally-sensitive optocoupler package comprising providing input signals across first and second input signal terminals of an LED included in the optocoupler package, generating and emitting, on the basis of the input signals, infrared or near-infrared light from the LED, and transmitting a portion of the light emitted by the LED and incident upon an upper surface of a layer comprising a thermally-sensitive material through the layer and a lower surface thereof towards a photodetector, wherein the LED is located above the upper surface of the layer, the photodetector is located beneath the lower surface of the layer, the thermally-sensitive material is configured such that an amount of light emitted by the LED, incident on the material, and transmitted through the material and the layer changes in accordance with changes in ambient temperature or local thermal conditions, and at least portions of the light transmitted through the layer are incident on the photodetector to provide isolated output signals therefrom.

Further embodiments are disclosed herein or will become apparent to those skilled in the art after having read and understood the specification and drawings hereof.

### BRIEF DESCRIPTION OF THE DRAWINGS

Different aspects of the various embodiments will become apparent from the following specification, drawings and claims in which:

FIGS. 1 and 2 illustrate two different embodiments of schematic circuit diagrams of optocoupler 8-pin DIP packages that may be employed in accordance with the teachings set forth herein;

FIG. 3 shows an 8-pin DIP package configuration corresponding to the embodiment of the circuitry shown in FIG. 1;

FIG. 4 shows a loop-powered 4-20 mA current loop circuit according to one embodiment of optocoupler package 10 disclosed herein;

FIG. 5 shows a high-speed low-cost analog isolator according to one embodiment of optocoupler package 10 disclosed herein, and

FIGS. 6 and 7 show cross-sectional views of one embodiment of optocoupler package 10 under different ambient temperature conditions, and correspondingly different optical transmissivity conditions, with respect to layer 24.

The drawings are not necessarily to scale. Like numbers refer to like parts or steps throughout the drawings.

### DETAILED DESCRIPTIONS OF SOME EMBODIMENTS

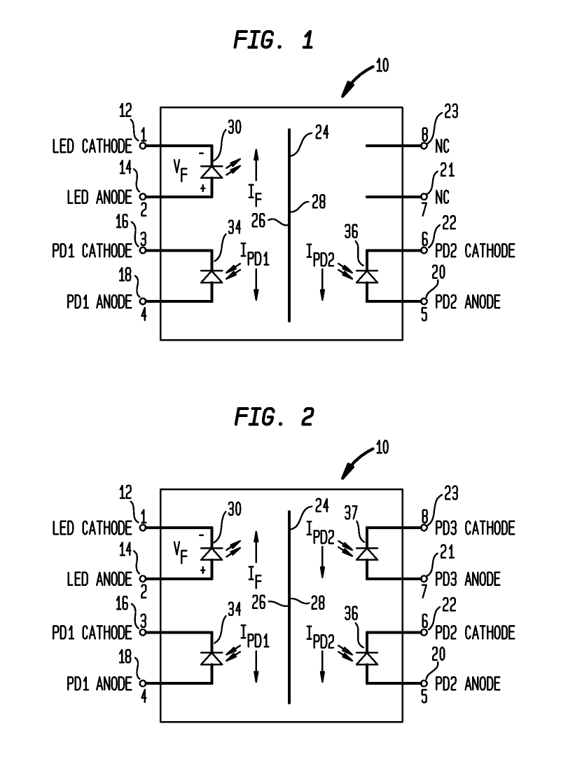

FIGS. 1 and 2 illustrate two different embodiments of schematic circuit diagrams of optocoupler 8-pin DIP packages that may be employed in accordance with the teachings set forth herein.

In FIG. 1, the embodiment of optocoupler package 10 shown therein comprises first and second input signal terminals 12 and 14 (pins 1 and 2, respectively), first and second output terminals 16 and 18 (pins 3 and 4, respectively), third and fourth output terminals 20 and 22 (pins 5 and 6, respectively), and layer 24 comprising a thermally or temperature-sensitive material, where the layer comprises upper surface 26 and lower surface 28. Light emitting diode (LED) 30 is operably connected to first and second input signal terminals 12 and 14 and is configured to emit infrared or near-infrared light in proportion to at least one predetermined characteristic of input signals received across first and second input signal terminals 12 and 14.

First photodetector 34 is operably connected to first and second output terminals 16 and 18 and according to one embodiment is configured to provide LED feedback control signals thereacross. Second photodetector 36 is operably connected to third and fourth output terminals 20 and 22 and according to one embodiment is configured to provide isolated output signals thereacross. Note that in other embodiments of optocoupler package 10 only one photodetector provides isolated output signals thereacross, as the feedback function provided by first photodetector 34 in the optocoupler package 10 shown in FIG. 1 is replaced at least in part by the temperature- or thermally-sensitive functionality of layer 24, more about which is said below.

Continuing to refer to FIG. 1, LED 30 is located above upper surface 26 of layer 24, while first detector may also be located above upper surface 26, or below lower surface 28. Second photodetector 36 is located beneath lower surface 28 of layer 24.

Still referring to FIG. 1, layer 24 comprises a thermally- or temperature-sensitive material, which is configured such that an amount of light emitted by LED 30, incident on layer 24 and the thermally-sensitive material disposed thereon or therein (or otherwise forming a portion or component thereof), and transmitted through the material and layer 24, changes in accordance with changes in ambient temperature or local thermal conditions, and at least portions of the light transmitted through layer 24 are incident on second photodetector 36 to provide the isolated output signals therefrom. That is, the optical transmissivity of layer 24, and more particularly the optical transmissivity of the thermally- or temperature-sensitive material incorporated into or onto layer 24, changes in accordance with changes in ambient temperature or local thermal conditions with respect to the wavelengths and frequencies of light emitted by LED 30, and that are incident on the thermally- or temperature-sensitive material of layer 24.

According to one embodiment of layer 24 and the thermally-sensitive material thereof, the amount of light transmitted through layer 24 increases as the ambient temperature increases. According to one embodiment of layer 24 and the thermally-sensitive material thereof, the amount of light transmitted through layer 24 decreases as the ambient temperature increases. In either such embodiment, temperature-modulated feedback control output signals generated by the optocoupler package may be employed to regulate and control the output of LED 30.

The thermally-sensitive material may be at least partially polymeric and/or comprises at least one film. If the thermally-sensitive material is an least partially polymeric film, it may also comprise a multi-layer optical film, which according to some embodiments may be a selective wavelength mirror multi-layer optical film. The film may include between about 100 layers and about 1,000 layers, and each of the layers may range, by way of example only, between about 10 nanometers and about 200 nanometers in thickness. One example of a material that may be modified for use as a thermally-sensitive material in layer 24 is 3M™ Cool Mirror Film 330™; provided, however, that the composition of such a film is modified to include appropriate thermally-sensitive materials./

According to some embodiments, the thermally-sensitive material may be at least partially thermochromic and configured to change its light transmissivity according to changes in ambient temperature. Such a thermochromic thermally-sensitive material may comprise, by way of example, vanadium dioxide and/or vanadium dioxide doped with titanium. The thermochromic thermally-sensitive material may also be contained in a coating disposed on layer 24, where layer 24 comprises a dielectric material upon which the thermochromic thermally-sensitive material is coated or otherwise disposed. In another embodiment, the thermally-sensitive material is at least partially thermo-opaque, temperature-activated, or electrochromic film or material that is configured to change its light transmissivity according to changes in ambient temperature or local thermal conditions.

Some examples of vanadium dioxide-based thermochromic thin films are set forth in the publication “Synthesis and characterization of VO₂-based thermochromic thin films for energy-efficient windows,” Batista et al., Nanoscale Research Letters, 2011, 6:301, the entirety of which is hereby incorporated by reference herein. Some examples of temperature-activated optical films are disclosed in U.S. Pat. No. 7,973,998 to Jiuzhi Xue entitled “Temperature Activated Optical Films,” Jul. 5, 2011, and in U.S. Patent Publication No. 2012/0002264 to Jiuzhi Xue entitled “Temperature Activated Optical Films,”, Jan. 5, 2012, the respective entireties of which are hereby incorporated by reference herein. Some examples of thermochromic filters are disclosed in U.S. Patent Publication No. 2010/0045924 to Powers et al. entitled “Methods for Fabricating Thermochromic Filters,” Feb. 25, 2010. See also European Patent EP 1 985 663 A1, Oct. 29, 2008 to DeArmitt entitled “Moulded Article with Temperature Dependent Transparency” and the publication “ThermoShift™: New Thermo-opaque Thermoplastics” to DeArmitt, unknown date of publication, which disclose thermo-opaque materials that change optical transparency with temperature, the respective entireties of which are hereby incorporated by reference herein. As those skilled in the art will now understand, some of the thermally-sensitive materials, filters and films described and disclosed in the foregoing publications and patent references may be adapted and configured for use in layer 24 and optocoupler package 10 disclosed herein.

It will now be seen that layer 24 and the thermally-sensitive material contained therein or thereon may be configured such that the optical transmissivity thereof varies in accordance with increases in temperature, or decreases in temperature. The rate at which such changes in optical transmissivity occur with temperature may also be configured according to the particular application at hand and the results that are desired. According to one embodiment, layer 24 and the thermally-sensitive material are configured such that the amount of light received by photodetector 36 remains approximately constant over a predefined range of ambient temperatures. For example, if LED 30 emits less light as ambient temperatures increase, layer 24 and the thermally-sensitive material may be configured such that the optical transmissivity of layer 24 increases with temperature, thereby causing optocoupler package 10 to produce isolated output signals that do not vary in amplitude, or that at least do not vary substantially in amplitude, owing to temperature-induced effects over a given range of ambient temperatures. In another example, if LED 30 emits more light as ambient temperatures increase, layer 24 and the thermally-sensitive material may be configured such that the optical transmissivity of layer 24 decreases with temperature, thereby causing optocoupler package 10 to produce isolated output signals that do not vary in amplitude, or that at least do not vary substantially in amplitude, owing to temperature-induced effects over a given range of ambient temperatures.

According to some embodiments, layer 24 may be configured as disclosed Referring now to FIG. 2, and in comparison to FIG. 1, there is included in optocoupler package 10 an additional third photodetector 37, which like photodetector 36 is configured to provide isolated output signals across the output terminals thereof (terminals 21 and 23, or pins 7 and 8).

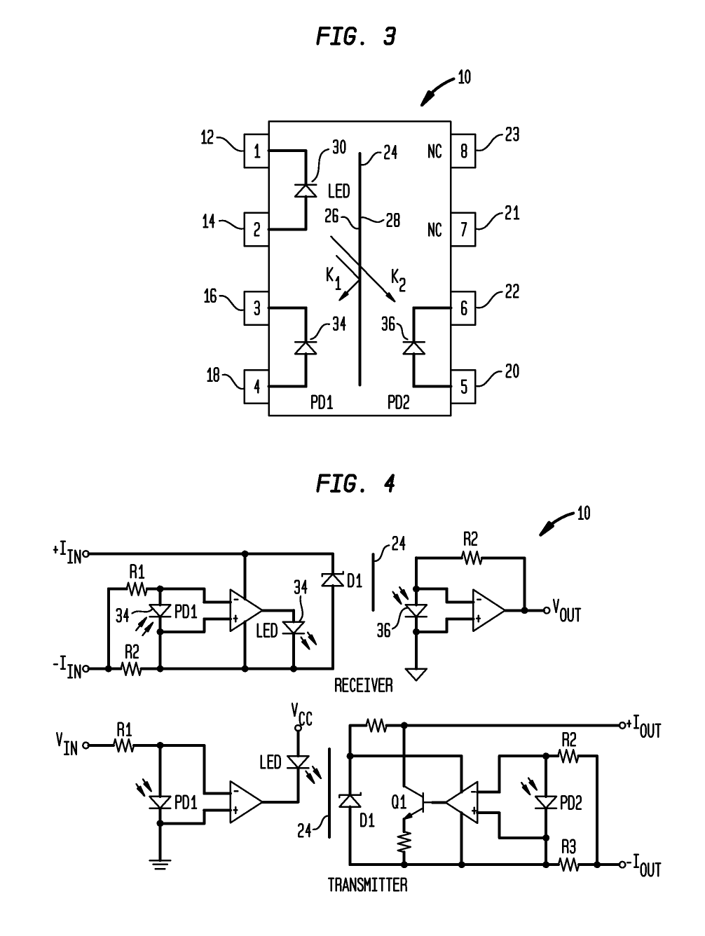

FIG. 3 shows an8-pin DIP package configuration corresponding to the embodiment of the circuitry shown in FIG. 1.

FIG. 4 shows a loop-powered 4-20 mA current loop circuit according to one embodiment of optocoupler package 10 disclosed herein.

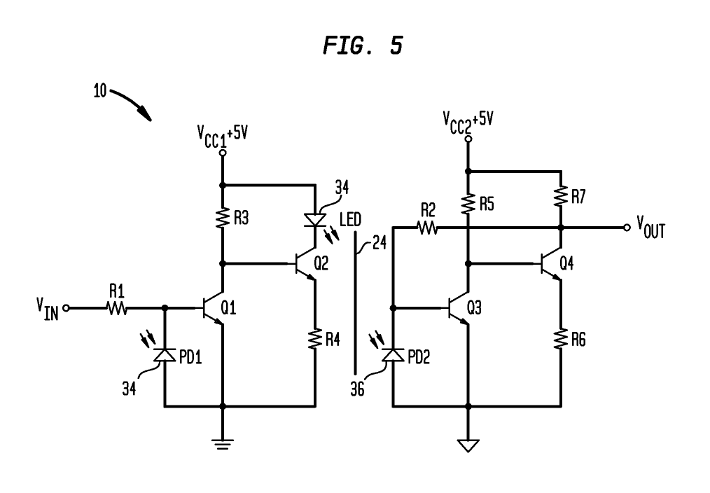

FIG. 5 shows a high-speed low-cost analog isolator according to one embodiment of optocoupler package 10 disclosed herein.

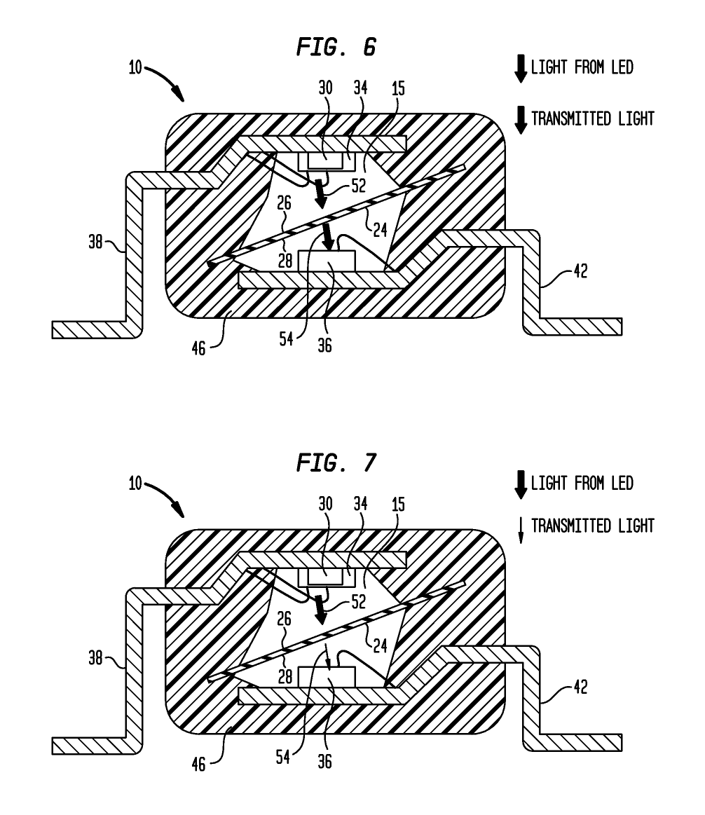

FIGS. 6 and 7 show cross-sectional views according to one embodiment of optocoupler package 10 comprising first input lead frame 38, second output lead frame 42, LED 30 mounted on first lead frame 38, first photodetector 34 mounted on first lead frame 38, second photodetector 36 mounted on second lead frame 42, and layer 24 disposed between inner portions of first and second lead frames 38 and 42, where layer 24 comprises a thermally-sensitive material whose optical transmissivity varies according to change sin ambient temperature, and where layer 24 comprises upper surface 26 and lower surface 28. Light emitting diode (LED) 30 is operably connected to first and second input signal terminals (not shown in FIG. 6) disposed on first lead frame 38 and is configured to emit infrared or near-infrared light in proportion to at least one predetermined characteristic of input signals received across the first and second input signal terminals. First photodetector 34 is mounted on first lead frame 38 operably connected to first and second output terminals (not shown in FIG. 6) and is configured to provide LED feedback control signals thereacross. Second photodetector 36 is mounted on second lead frame 42 and is operably connected to third and fourth output terminals (not shown in FIG. 6) and is configured to provide isolated output signals thereacross.

Continuing to refer to FIG. 6, LED 30 and first photodetector 34 are both located above upper surface 26 of layer 24 of layer 24. Second photodetector 36 is located beneath lower surface 28 of layer 24. As described above, layer 24 comprises a thermally-sensitive material, which is configured such that an amount of light emitted by LED 30, incident on layer 24 and the thermally-sensitive material disposed thereon or therein (or otherwise forming a portion or component thereof), and transmitted through the material and layer 24, changes in accordance with changes in ambient temperature, and at least portions of the light transmitted through layer 24 are incident on second photodetector 36 to provide the isolated output signals therefrom. That is, the optical transmissivity of layer 24,and more particularly the optical transmissivity of the thermally-sensitive material incorporated into or onto layer 24, changes in accordance with changes in ambient temperature with respect to the wavelengths and frequencies of light emitted by LED 30 and that are incident on the thermally-sensitive material of layer 24. This is shown by comparing FIGS. 6 and 7. In FIG. 6 most or substantially all of the light incident on upper surface 26 that has been emitted by LED 30 is transmitted through the thermally-sensitive material included in layer 24 for incidence on photodetector 36. In FIG. 7, and owing to a change in ambient temperature, a reduced amount of the light incident on upper surface 26 that has been emitted by LED 30 is transmitted through the thermally-sensitive material included in layer 24 for incidence on photodetector 36.

Note that various embodiments of layer 24 in optocoupler package 10 may further comprise a dielectric semi-reflective material configured to reflect a first portion of light generated by LED 30 and incident upon upper surface 26 of layer 24 towards first photodetector 34 thereby to provide LED feedback control signals therefrom, as disclosed and taught in the above-referenced and incorporated '227 patent application. Such a dielectric semi-reflective material in layer 24 may be further configured to transmit a second portion of light generated by LED 30 through upper and lower surfaces 26 and 28 of layer 24 for detection by second photodetector 36 to provide isolated output signals therefrom.

In the various embodiments of optocoupler package 10, the first, second or third photodetectors may be a photo diode, a bipolar detector transistor, or a Darlington detector transistor. LED 30 may be an AlGaAs LED, an ACE AlGaAs LED, a DPUP AlGaAs LED, or a GaAsP LED.

As shown in FIGS. 6 and 7, optocoupler package 10 may also comprise a molding compound 46 that at least partially surrounds or encases a plurality of terminals 12, 14, 16, 18, 20, 22, 21 or 23 and portions of layer 24 of dielectric optically semi-reflective and transmissive material. Molding compound 46 may comprise, by way of example, plastic or any other suitable material. In one embodiment, optocoupler package 10 is an 8-pin DIP package, although other packaging configurations are certainly contemplated.

As described above, the LED feedback control signals provided by first photodetector 34 may be employed to regulate and control the output of LED 30. The at least one predetermined characteristic of the input signals employed to modulate light emitted by LED 30 may include one or more of input signal amplitude, phase and frequency.

Referring now to FIGS. 1 through 7, according to some embodiments there are also provided corresponding methods of operating an optocoupler package 10, which may include providing input signals across first and second input signal terminals 12 and 14 of LED 30, generating and emitting, on the basis of the input signals, infrared light signals with LED 30, transmitting an amount of light generated by LED 30 through upper surface 26 and opposing lower surface 28 of layer 24 comprising the thermally-sensitive material, and varying the amount of such light in accordance with changes in ambient temperature, towards second photodetector 36 thereby to generate and provide isolated output signals therefrom, where second photodetector 36 is located beneath lower surface 28. Such methods may further include one or more of regulating and controlling the output of LED 30 using temperature-modulated feedback control output signals generated by optocoupler package 10, increasing the amount of light transmitted through layer 24 as the ambient temperature increases, decreasing the amount of light transmitted through layer 24 as the ambient temperature increases, providing an at least partially polymeric material for the thermally-sensitive material, providing a film as the thermally-sensitive material, and providing a thermochromic material as the thermally-sensitive material.

Various optocouplers and optocoupler packages known in the art may be adapted for use in accordance with the above teachings. Examples of such optocouplers and optocoupler packages include, but are not limited to: (a) Avago Technologies™ “6N135/6, HCNW135/6, HCPL-2502/0500/0501 Single Channel, High Speed Optocouplers,” Jan. 29, 2010; (b) Avago Technologies™ HCPL-7710/0710 40 ns Propagation Delay CMOS Optocoupler,” Jan. 4, 2008; and (c) Avago Technologies™ “6N137, HCNW2601, HCNW2611, HCPL-0600, HCPL-0601, HCPL-0611, HCPL-0630, HCPL-0631, HCPL-0661, HCPL-2601, HCPL-2611, HCPL-2630, HCPL-2631, HCPL-4661 High CMR, High Speed TTL Compatible Optocouplers,” Mar. 29, 2010; the respective Data Sheets for which are filed on even date herewith in an accompanying Information Disclosure Statement and which are hereby incorporated by reference herein, each in its respective entirety.

The above-described embodiments should be considered as examples of the present invention, rather than as limiting the scope of the invention. In addition to the foregoing embodiments of the invention, review of the detailed description and accompanying drawings will show that there are other embodiments of the present invention. Accordingly, many combinations, permutations, variations and modifications of the foregoing embodiments of the present invention not set forth explicitly herein will nevertheless fall within the scope of the present invention.

We claim:

1. A thermally-sensitive optocoupler package, comprising:
a layer comprising a thermally-sensitive material, the layer having an upper surface and a lower surface;
at least one light emitting diode (LED) configured to emit infrared or near-infrared light in proportion to at least one predetermined characteristic of the input signals, and
at least one photodetector configured to provide isolated output signals therefrom;
wherein the LED is located above the upper surface of the layer, the photodetector is located beneath the lower surface of the layer, the thermally-sensitive material is configured such that an amount of light emitted by the LED, incident on the material, and transmitted through the material and the layer changes in accordance with changes in ambient temperature or local thermal conditions, and at least portions of the light transmitted through the layer are incident on the photodetector to provide the isolated output signals therefrom.

2. The thermally-sensitive optocoupler package of claim 1, wherein the amount of light transmitted through the layer increases as the ambient temperature increases.

3. The thermally-sensitive optocoupler package of claim 2, wherein temperature-modulated feedback control output signals generated by the optocoupler package are employed to regulate and control the output of the LED.

4. The thermally-sensitive optocoupler package of claim 1, wherein the amount of light transmitted through the layer decreases as the ambient temperature increases.

5. The thermally-sensitive optocoupler package of claim 4, wherein temperature-modulated feedback control output signals generated by the optocoupler package are employed to regulate and control the output of the LED.

6. The thermally-sensitive optocoupler package of claim 1, wherein the thermally-sensitive material is at least partially polymeric.

7. The thermally-sensitive optocoupler package of claim 6, wherein the thermally-sensitive material further comprises at least one film.

8. The thermally-sensitive optocoupler package of claim 7, wherein the at least partially polymeric film is a multi-layer optical film.

9. The thermally-sensitive optocoupler package of claim 8, wherein the multi-layer optical film is a selective wavelength mirror multi-layer optical film.

10. The thermally-sensitive optocoupler package of claim 9, wherein the film comprises between about 100 layers and about 1,000 layers.

11. The thermally-sensitive optocoupler package of claim 10, wherein each of the layers ranges between about 10 nanometers and about 200 nanometers in thickness.

12. The thermally-sensitive optocoupler package of claim 1, wherein the thermally-sensitive material is at least partially thermochromic.

13. The thermally-sensitive optocoupler package of claim 12, wherein the material further comprises vanadium dioxide.

14. The thermally-sensitive optocoupler package of claim 12, wherein the material further comprises titanium.

15. The thermally-sensitive optocoupler package of claim 12, wherein the thermochromic material is contained in a coating disposed on the layer.

16. The thermally-sensitive optocoupler package of claim 15, wherein the layer further comprises a dielectric material upon which the thermochromic material is coated.

17. The thermally-sensitive optocoupler package of claim 1, wherein the thermally-sensitive material is at least partially electrochromic.

18. The thermally-sensitive optocoupler package of claim 1, wherein the at least one predetermined characteristic includes at least one of input signal amplitude, phase and frequency.

19. The thermally-sensitive optocoupler package of claim 1, wherein the photodetector is one of a photo diode, a bipolar detector transistor, and a Darlington detector transistor.

20. The thermally-sensitive optocoupler package of claim 1, wherein the LED is one of an AlGaAs LED, an ACE AlGaAs LED, a DPUP AlGaAs LED, and a GaAsP LED.

21. The thermally-sensitive optocoupler package of claim 1, wherein the optocoupler further comprises a molding compound that at least partially surrounds or encases the LED, the photodetector, and the layer.

22. The thermally-sensitive optocoupler package of claim 1, wherein the optocoupler is an 8-pin DIP package.

23. A method of operating a thermally-sensitive optocoupler package, comprising:
providing input signals across first and second input signal terminals of an LED included in the optocoupler package;
generating and emitting, on the basis of the input signals, infrared or near-infrared light from the LED, and
transmitting a portion of the light emitted by the LED and incident upon an upper surface of a layer comprising a thermally-sensitive material through the layer and a lower surface thereof towards a photodetector;
wherein the LED is located above the upper surface of the layer, the photodetector is located beneath the lower surface of the layer, the thermally-sensitive material is configured such that an amount of light emitted by the LED, incident on the material, and transmitted through the material and the layer changes in accordance with changes in ambient temperature or local thermal conditions, and at least portions of the light transmitted through the layer are incident on the photodetector to provide isolated output signals therefrom.

24. The method of claim 23, further comprising regulating and controlling the output of the LED using temperature-modulated feedback control output signals generated by the optocoupler package.

25. The method of claim 23, wherein the amount of light transmitted through the layer increases as the ambient temperature increases.

26. The method of claim 23, wherein the amount of light transmitted through the layer decreases as the ambient temperature increases.

27. The method of claim 23, wherein the thermally-sensitive material is at least partially polymeric.

28. The method of claim 23, wherein the thermally-sensitive material further comprises at least one film.

29. The method of claim 23, wherein the thermally-sensitive material further comprises a thermochromic material.
